(19) United States
(12) Patent Application Publication
(10) Pub. No.: US 2022/0314396 A1
(43) Pub. Date: Oct. 6, 2022

(54) DETERMINING METHOD AND WRITING METHOD

(71) Applicant: DISCO CORPORATION, Tokyo (JP)

(72) Inventor: Nobukazu DEJIMA, Tokyo (JP)

(21) Appl. No.: 17/657,510

(22) Filed: Mar. 31, 2022

(30) Foreign Application Priority Data
Apr. 2, 2021 (JP) 2021-063375

(51) Int. Cl. B24B 49/18

(52) U.S. Cl. CPC B24B 49/18

(57) ABSTRACT

A determining method includes performing processing according to a processing condition by using a grindstone tool, and writing processing information to an IC tag provided to the grindstone tool or a case configured to house the grindstone tool, the processing information each including information about a workpiece, the processing condition, and an amount of wear of the grindstone tool, reading the processing information written to the IC tag, and generating wear tendency information by determining a wear tendency of the grindstone tool from a relation between a cumulative processing amount of the workpiece, the cumulative processing amount being obtained from the processing information, and a cumulative wear amount of the grindstone tool, the cumulative wear amount corresponding to the cumulative processing amount, and determining propriety of the grindstone tool or the processing condition for the workpiece on a basis of the wear tendency information.

### BACKGROUND OF THE INVENTION

### Field of the Invention

The present invention relates to a writing method of writing, to an integrated circuit (IC) tag, processing information about processing performed with a grindstone tool such as a cutting blade or a grinding stone, and a determining method of determining propriety of the grindstone tool or processing conditions on the basis of the processing information.

### Description of the Related Art

In a process of manufacturing device chips to be incorporated into an electronic apparatus, a plate-shaped workpiece typified by a semiconductor wafer or a resin package substrate is cut and divided into individual pieces by a cutting apparatus including an annular cutting blade (see Japanese Patent Laid-Open No. Sho 62-53804). The cutting apparatus is fitted with a cutting blade referred to as a hub type including an annular base formed of aluminum or the like and a grindstone portion fixed to an outer circumferential portion of the base. The cutting blade is used for the cutting of the workpiece. In addition, in order to obtain thin device chips, the workpiece before being divided into individual pieces is ground by a grinding apparatus including grinding stones. The grinding apparatus is fitted with a grinding wheel having the grinding stones annularly arranged on one surface thereof. A processing apparatus such as the cutting apparatus or the grinding apparatus processes various types of workpieces. There are various types of grindstone tools such as cutting blades or grinding stones which types correspond to various kinds of workpieces. An appropriate type of grindstone tool matching the type of a workpiece is fitted to the processing apparatus in advance. The processing apparatus processes the workpiece with the grindstone tool under predetermined processing conditions corresponding to the type of the workpiece. Then, when the type of the workpiece is to be changed, or when a problem occurs in the processing apparatus, the old grindstone tool is removed from the processing apparatus, and a new grindstone tool is fitted to the processing apparatus.

The old grindstone tool removed from the processing apparatus is housed and stored in a case. At this time, a usage history is preferably managed in preparation for the reuse or verification of the grindstone tool. Accordingly, for example, a cutting blade or a blade case is used which incorporates an IC tag in which usage history information of the cutting blade can be registered (see Japanese Patent Laid-Open No. 2006-51596 and Japanese Patent Laid-Open No. 2016-64476). When the cutting blade is reused in the cutting apparatus, the usage history information is read from the IC tag, and a height of the cutting blade is adjusted according to usage conditions of the cutting blade. When the processing apparatus is to process a new type of workpiece for which there has been no processing experience thus far, it is necessary to search for an optimum type of a grindstone tool and optimum processing conditions that make it possible to process the workpiece with high quality. Therefore, in the processing apparatus, test processing is performed while the type of the grindstone tool and the processing conditions are changed variously, and a processing result is evaluated.

### SUMMARY OF THE INVENTION

Recently, applications of device chips have been diversified, and a wide variety of device chips supporting the respective applications are manufactured one after another. Therefore, the test processing for searching for the optimum processing conditions or the like is repeated daily. However, there is a case where a sufficient number of dummy products that can be used as a workpiece at a time of the test processing are not secured, or there is a case where a sufficient time cannot be taken for the test processing. In this case, the mass production of device chips is started while the type of the grindstone tool and the processing conditions cannot be verified sufficiently. There may be a risk of causing a large-scale quality defect problem when device chips are manufactured by processing workpieces with the grindstone tool and the processing conditions selected without undergoing sufficient verification, and then the device chips are put on the market. Furthermore, recently, there has been a remarkable tendency for higher functionality of devices, and quality desired of device chips has tended to become high, so that a degree of difficulty in optimizing the processing conditions has been rising increasingly.

It is accordingly an object of the present invention to provide a determining method capable of determining, on the basis of processing information, whether or not a grindstone tool and processing conditions are suitable for processing a workpiece and a writing method of writing the processing information to an IC tag.

In accordance with an aspect of the present invention, there is provided a determining method for determining propriety of a grindstone tool or a processing condition, the determining method including a writing step of performing processing according to the processing condition by using the grindstone tool, and writing a plurality of pieces of processing information of the grindstone tool to an IC tag provided to the grindstone tool or a case configured to house the grindstone tool, the plurality of pieces of processing information of the grindstone tool each including information about a workpiece processed by the grindstone tool, the processing condition under which the workpiece is processed by the grindstone tool, and an amount of wear of the grindstone tool at a time of processing the workpiece, a wear tendency information generating step of reading the processing information written to the IC tag in the writing step, and generating wear tendency information by determining a wear tendency of the grindstone tool from a relation between a cumulative processing amount of the workpiece, the cumulative processing amount being obtained from the processing information, and a cumulative wear amount of the grindstone tool, the cumulative wear amount corresponding to the cumulative processing amount; and a determining step of making determination of the propriety of the grindstone tool or the processing condition for the workpiece on a basis of the wear tendency information generated in the wear tendency information generating step.

In accordance with another aspect of the present invention, there is provided a writing method of writing processing information of a grindstone tool to an IC tag. The writing method includes performing processing according to a processing condition by using the grindstone tool, and writing the processing information of the grindstone tool to the IC tag provided to the grindstone tool or a case configured to house the grindstone tool, the processing information of the grindstone tool including information about a workpiece processed by the grindstone tool, the processing condition under which the workpiece is processed by the grindstone tool, and an amount of wear of the grindstone tool at a time of processing the workpiece.

In accordance with a further aspect of the present invention, there is provided a determining method of determining propriety of a grindstone tool or a processing condition. The determining method includes a wear tendency information generating step of reading processing information written to an IC tag to which the processing information is written and which is provided to the grindstone tool or a case configured to house the grindstone tool, the processing information including information about a workpiece cut by the grindstone tool, the processing condition under which the workpiece is processed by the grindstone tool, and an amount of wear of the grindstone tool at a time of processing the workpiece, and generating wear tendency information by determining a wear tendency of the grindstone tool from a relation between a cumulative processing amount of the workpiece, the cumulative processing amount being obtained from the processing information, and a cumulative wear amount of the grindstone tool, the cumulative wear amount corresponding to the cumulative processing amount; and a determining step of making determination of the propriety of the grindstone tool or the processing condition for the workpiece on a basis of the wear tendency information generated in the wear tendency information generating step.

Preferably, the wear tendency information generating step generates a graph indicating the wear tendency of the grindstone tool.

In addition, preferably, the determining step makes the determination by comparing reference wear tendency information about a reference wear tendency of the grindstone tool and the wear tendency information with each other.

In addition, more preferably, the wear tendency information generating step generates a graph functioning as the wear tendency information, and the determining step makes the determination by comparing a reference graph functioning as the reference wear tendency information and the graph with each other.

In addition, preferably, the grindstone tool is a cutting blade.

The determining method and the writing method according to one aspect of the present invention use the grindstone tool provided with the IC tag or the case provided with the IC tag. The processing information including the executed processing condition in addition to the information about the processed workpiece and the amount of wear of the grindstone tool is written to and stored in the IC tag. Then, when the stored processing information is read from the IC tag, the propriety of the grindstone tool and the processing condition can be evaluated. Therefore, even in a case where the mass production of device chips is started without test processing being able to be performed sufficiently, it is possible to evaluate and improve the grindstone tool and the processing condition while proceeding with the manufacturing of the device chips. The risk of a problem of a quality defect in the device chips is therefore reduced.

Hence, one aspect of the present invention provides a determining method capable of determining whether or not a grindstone tool and a processing condition are suitable for processing a workpiece on the basis of processing information and a writing method of writing the processing information to an IC tag.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting an example of a configuration of a cutting apparatus;

FIG. 2 is an exploded perspective view schematically depicting an example of a configuration of a cutting unit;

FIG. 3 is a perspective view schematically depicting an example of a configuration of a blade case;

FIG. 4 is a plan view schematically depicting the example of the configuration of the blade case;

FIG. 5 is a perspective view schematically depicting an example of a configuration of a blade case holder;

FIG. 6A is a perspective view schematically depicting a blade edge position detecting unit;

FIG. 6B is a side view schematically depicting the blade edge detecting unit;

FIG. 7A is a graph schematically depicting an example of a relation between a processing distance and a blade edge remaining amount of a cutting blade;

FIG. 7B is a graph schematically depicting another example of the relation between the processing distance and the blade edge remaining amount of the cutting blade;

FIG. 8 is a graph schematically depicting decreasing tendencies of the blade edge remaining amount; and

FIG. 9 is a flowchart depicting a flow of steps of a determining method according to an embodiment.

### DETAILED DESCRIPTION OF THE PREFERRED EMBODIMENT

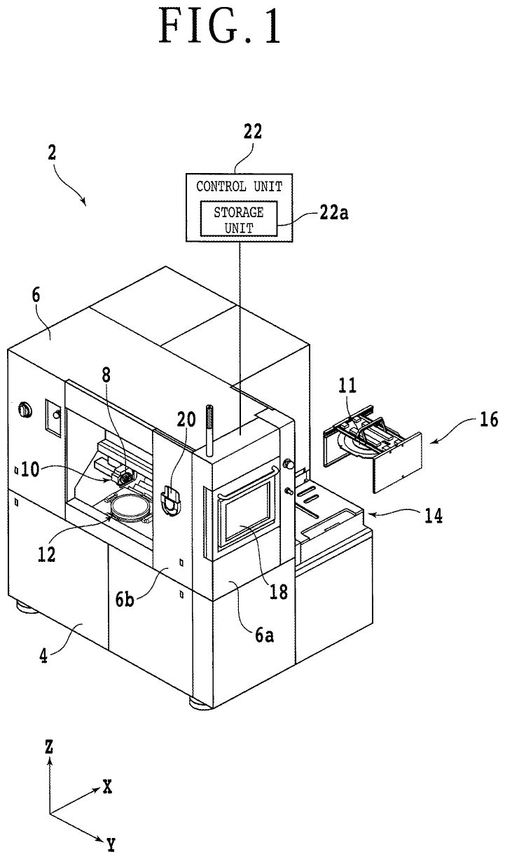

An embodiment of the present invention will hereinafter be described in detail with reference to the accompanying drawings. Description will first be made of a cutting apparatus as a processing apparatus used in a state of being fitted with a cutting blade as a grindstone tool. FIG. 1 is a perspective view schematically depicting an example of a configuration of a cutting apparatus (processing apparatus) 2.

A workpiece to be processed by the cutting apparatus 2 is, for example, a substantially disk-shaped wafer formed of silicon (Si), silicon carbide (SiC), gallium nitride (GaN), gallium arsenide (GaAs), or another semiconductor material. Alternatively, the workpiece is a plate-shaped substrate or the like formed of a material such as sapphire, quartz, glass, or ceramic. The glass is, for example, an alkali glass, a non-alkali glass, a soda-lime glass, a lead glass, a borosilicate glass, a quartz glass, or the like. The top surface of the workpiece, for example, has a plurality of devices such as ICs or large scale integration (LSI) formed thereon. Planned dividing lines are set between the devices on the workpiece. Then, individual device chips can be formed when the workpiece is divided by cutting the workpiece along the planned dividing lines by the cutting apparatus 2. Incidentally, when a grinding apparatus including a grinding wheel having grinding stones (grindstone tool) annularly disposed thereon thins the workpiece before being divided, thin device chips are ultimately obtained.

The workpiece is, for example, affixed onto a tape affixed to an annular frame, and is handled as a part of a frame unit 11 integral with the annular frame. FIG. 1 includes a perspective view schematically depicting the frame unit 11. When the workpiece is handled by using the annular frame and the tape, the workpiece can be protected from an impact occurring at a time of transportation. Further, when the tape is expanded, intervals between chips formed by dividing the workpiece are increased, and therefore it becomes easy to pick up the chips.

In the following, description will be made by taking as an example a case where the processing apparatus including the grindstone tool for processing the workpiece is the cutting apparatus 2 and the workpiece is processed by a cutting blade 8 as the grindstone tool. However, the processing apparatus and the grindstone tool are not limited to this. The cutting apparatus (processing apparatus) 2 includes a base 4 that supports each constituent element. A cover 6 that covers the base 4 is provided to the upper side of the base 4. A space is formed within the cover 6. The space houses a cutting unit 10 including the cutting blade (grindstone tool) 8. The cutting unit 10 is moved in a front-rear direction (a Y-axis direction or an indexing feed direction) by a cutting unit moving mechanism (not depicted). A chuck table 12 that sucks and holds the workpiece is provided below the cutting unit 10. The chuck table 12 is moved in a left-right direction (an X-axis direction or a processing feed direction) by a chuck table moving mechanism (not depicted), and is rotated about a vertical axis (Z-axis) by a rotating mechanism (not depicted).

A cassette elevator 14 is disposed on a corner portion of the base 4. A cassette 16 that can house a plurality of workpieces is mounted on the upper surface of the cassette elevator 14. The cassette elevator 14 is configured to be raisable and lowerable. The cassette elevator 14 adjusts the position of the cassette 16 in a height direction (Z-axis direction) so that the workpieces can be unloaded from and loaded into the cassette 16.

A touch panel type monitor 18 serving as a user interface is provided to a front surface 6a of the cover 6. In addition, a blade case holder 20 is disposed on a side surface 6b of the cover 6. Details of the blade case holder 20 will be described later. The monitor 18 is connected to a control unit 22 that controls each part of the cutting apparatus 2. The control unit 22 controls the operation of the cutting unit 10, the cutting unit moving mechanism, the chuck table 12, the chuck table moving mechanism, and the like on the basis of processing conditions set through the monitor 18 and the like.

The control unit 22 is, for example, constituted by a computer including a processing apparatus such as a processor typified by a central processing unit (CPU), a main storage apparatus such as a dynamic random access memory (DRAM), a static random access memory (SRAM), or a read only memory (ROM), and an auxiliary storage apparatus such as a flash memory, a hard disk drive, or a solid-state drive. The auxiliary storage apparatus stores software including a predetermined program. By making the processing apparatus operate according to the software, the control unit 22 functions as concrete means in which the software and the processing apparatus (hardware resources) cooperate with each other. Incidentally, the auxiliary storage apparatus functions as a storage unit 22a that stores the software and various kinds of information.

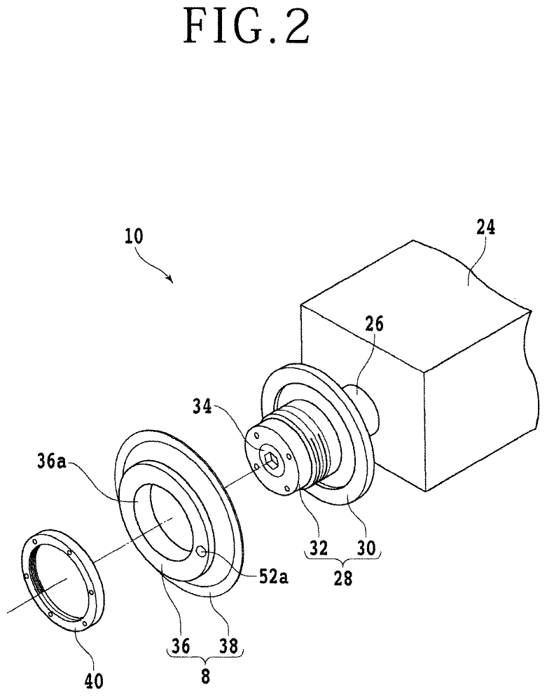

FIG. 2 is an exploded perspective view schematically depicting an example of a configuration of the cutting unit 10. Incidentally, FIG. 2 omits a part of constituent elements of the cutting unit 10. As depicted in FIG. 2, the cutting unit 10 includes a spindle 26 rotatably supported by a spindle housing 24. A flange mechanism 28 for fixing the cutting blade 8 is fitted to a distal end portion of the spindle 26. The flange mechanism 28 includes a flange portion 30 extended radially outward and a boss portion 32 projecting from the surface (front surface) of the flange portion 30. A fitting portion (not depicted) to be fitted with the distal end portion of the spindle 26 is formed on the back surface (rear surface) side of the flange portion 30. The flange mechanism 28 is fixed to the spindle 26 when a bolt 34 is fastened in a state in which the distal end portion of the spindle 26 is fitted in the fitting portion.

The cutting blade 8 is a generally-called hub blade. The cutting blade 8 has a ring-shaped grindstone portion (cutting edge) 38 fixed to the outer circumference of a disk-shaped supporting base 36. An opening 36a into which to insert the boss portion 32 of the flange mechanism 28 is formed in a center of the supporting base 36. The cutting blade 8 is fitted to the flange mechanism 28 by inserting the boss portion 32 into the opening 36a. The supporting base 36 is, for example, formed of a metallic material such as aluminum or stainless steel. The grindstone portion 38 is formed on the outer circumference of the supporting base 36 by a method such as electroplating. In addition, the grindstone portion 38 may be provided with an IC tag 52a that stores processing information received in a noncontact manner (wirelessly), and transmits the stored processing information in a noncontact manner (wirelessly). The IC tag 52a may be described as a wireless IC tag, a radio frequency identifier (RFID) tag, or the like.

The grindstone portion 38 is, for example, formed in an annular shape by mixing abrasive grains of diamond, cubic boron nitride (CBN), or the like in a binder such as a vitrified binder, a resinoid, or a metal (typically nickel). It is to be noted that while a hub blade is described as the cutting blade 8 in the present embodiment, a generally-called washer blade formed of only a grindstone portion may be used. An annular fixing ring 40 is attached to a distal end portion of the boss portion 32 in a state in which the cutting blade 8 is fitted to the flange mechanism 28. The cutting blade 8 is thereby sandwiched between the flange mechanism 28 and the fixing ring 40.

The cutting unit 10 is provided with a reader-writer (not depicted) for reading the processing information from the IC tag 52a provided to the cutting blade 8, and writes the processing information to the IC tag 52a. This reader-writer is disposed at a position corresponding to the IC tag 52a of the cutting blade 8 fitted to the flange mechanism 28, and is connected to the control unit 22.

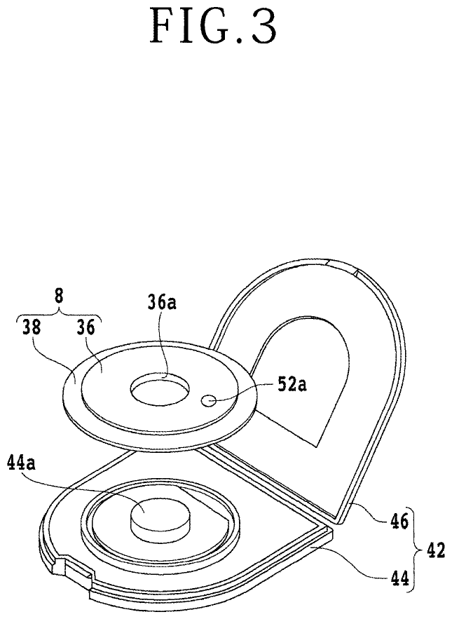

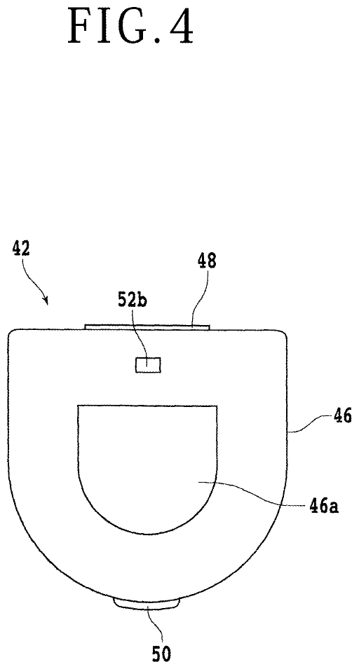

A blade case that houses the cutting blade 8 will next be described as a case that houses the grindstone tool. However, the case is not limited to the blade case. The case is of a configuration suitable for housing the grindstone tool as an object to be housed. FIG. 3 is a perspective view schematically depicting an example of a configuration of the blade case that houses the cutting blade 8. FIG. 4 is a plan view schematically depicting the example of the configuration of the blade case. As depicted in FIG. 3, a blade case 42 includes a housing portion 44 that houses the cutting blade 8, and a lid portion 46 that prevents the cutting blade 8 housed in the housing portion 44 from falling off.

The housing portion 44 and the lid portion 46 are a plate-shaped member in a semi-rectangular shape formed by cutting away two adjacent corner portions into the shape of an arc. The housing portion 44 and the lid portion 46 are coupled to each other by a coupling portion 48 (FIG. 4) provided to a periphery on a side not cut away. The coupling portion 48 functions as a hinge for opening and closing the lid portion 46 with respect to the housing portion 44. A pawl portion 50 is formed on a periphery on a side opposite to the coupling portion 48. A protruding portion 44a in a cylindrical shape is formed on an inner surface of the housing portion 44 which inner surface faces the lid portion 46. The cutting blade 8 can be housed within the blade case 42 by inserting the protruding portion 44a into the opening 36a of the cutting blade 8, and closing the lid portion 46. As depicted in FIG. 4, an IC tag 52b that stores processing information received in a noncontact manner (wirelessly), and transmits the stored processing information in a noncontact manner (wirelessly) may be provided on the coupling portion 48 side of the lid portion 46. Incidentally, the IC tag 52b may be provided to the housing portion 44.

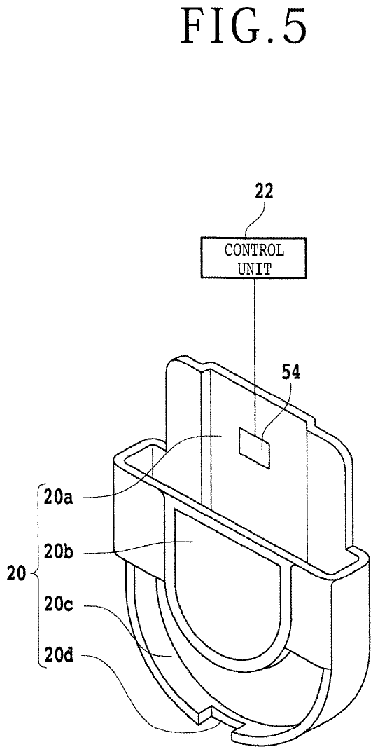

FIG. 5 is a perspective view schematically depicting an example of a configuration of the blade case holder 20. The blade case holder 20 is, for example, used to hold the blade case 42 that becomes empty after the mounting of the cutting blade 8. As depicted in FIG. 5, the blade case holder 20 includes a holding portion 20b having a slit-shaped opening into which to insert the blade case 42. A supporting portion 20c that supports, from below, the pawl portion 50 side of the blade case 42 inserted in the holding portion 20b is disposed below the holding portion 20b. A notch portion 20d notched so as to correspond to the pawl portion 50 is formed in the supporting portion 20c.

In addition, the blade case holder 20 has a groove portion 20a corresponding to a protruding portion 46a (FIG. 4) formed on the external surface of the lid portion 46. The blade case 42 is inserted into the holding portion 20b with the pawl portion 50 side oriented downward so as to slide the protruding portion 46a along the groove portion 20a. The groove portion 20a is provided with a reader-writer (reading and writing means) 54 for reading the processing information from the IC tag 52b provided to the blade case 42, and writes processing information to the IC tag 52b. The reader-writer 54 is disposed at a position corresponding to the IC tag 52b of the blade case 42 held by the blade case holder 20, and is connected to the control unit 22. The reader-writer 54 includes an antenna for transmitting and receiving the processing information.

The description of the cutting apparatus 2 will be continued. When the cutting of the workpiece is to be performed, the cutting blade 8 is extracted from the blade case 42, and the cutting blade 8 is fixed to the distal end of the spindle 26 by the flange mechanism 28. At this time, the blade case 42 is preferably stored in a state of being housed in the blade case holder 20. Then, the frame unit 11 is held by the chuck table 12. Thereafter, the cutting blade 8 is rotated by rotating the spindle 26, and the cutting unit 10 is lowered to a predetermined height position. Then, the workpiece is cut by moving the chuck table 12 along the processing feed direction, and making the grindstone portion 38 of the rotating cutting blade 8 cut into the workpiece.

When the workpiece cutting using the cutting blade 8 is repeated, the grindstone portion 38 of the cutting blade 8 is worn, and the diameter of the cutting blade 8 is decreased gradually. Then, the height position of a lower end of the grindstone portion 38 of the cutting blade 8 rises gradually. Accordingly, after the cutting blade 8 cuts workpieces, a setup process is periodically performed so that the lower end of the grindstone portion 38 of the cutting blade 8 can be located at a height position suitable for cutting. The setup process detects a reference height of the cutting unit 10 as a height position of the cutting unit 10 when the height of the lower end of the grindstone portion 38 of the cutting blade 8 is located at a predetermined position suitable for cutting the workpiece. Incidentally, the setup process is performed also when the cutting blade 8 is attached to the cutting unit 10.

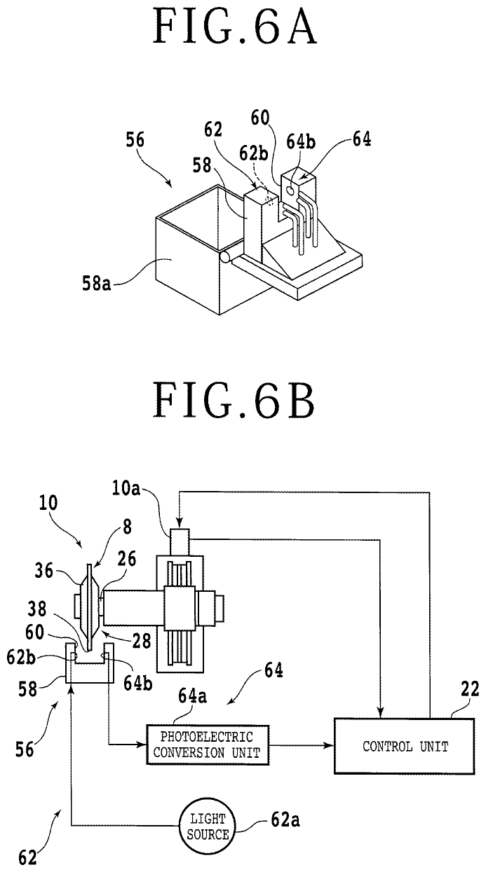

FIG. 6A is a perspective view schematically depicting a blade edge position detecting unit 56 used when the setup process is performed. FIG. 6B is a conceptual diagram schematically depicting the cutting unit 10, the blade edge position detecting unit 56, and the control unit 22. The blade edge position detecting unit 56 is disposed in the vicinity of the cutting unit 10. A main body 58 of the blade edge position detecting unit 56 is provided with a groove-shaped blade advance portion 60 that opens upward. When the blade edge position detecting unit 56 is used, the cutting blade 8 is positioned above the blade advance portion 60, and the cutting blade 8 is advanced into the blade advance portion 60 by lowering the cutting blade 8.

One side wall of the blade advance portion 60 is provided with a light emitting unit 62. Another side wall of the blade advance portion 60 is provided with a light receiving unit 64 at a position opposed to the light emitting unit 62. That is, the light emitting unit 62 and the light receiving unit 64 face each other with the blade advance portion 60 interposed therebetween. The light emitting unit 62 includes a light emitting window 62b and a light source 62a connected to the light emitting window 62b via an optical fiber or the like. When the light source 62a is actuated, light is emitted from the light emitting window 62b. The light receiving unit 64 includes a light receiving window 64b and a photoelectric conversion unit 64a connected to the light receiving window 64b via an optical fiber or the like. The light reaching the light receiving window 64b is received by the photoelectric conversion unit 64a. An electric signal having a voltage value corresponding to an amount of the received light is output from the photoelectric conversion unit 64a. The photoelectric conversion unit 64a is electrically connected to the control unit 22. The photoelectric conversion unit 64a sends the electric signal to the control unit 22.

The light emitting window 62b and the light receiving window 64b are arranged at a substantially same height position. The height position is a height position in the vicinity of the lower end of the grindstone portion 38 of the cutting blade 8 when the cutting unit 10 is located at a reference position suitable for cutting processing. The blade edge position detecting unit 56 is provided with an openable and closable cover 58a that protects the light emitting unit 62 and the light receiving unit 64 during non-use of the blade edge position detecting unit 56. At a time of use of the blade edge position detecting unit 56, the cover 58a is opened in advance, and the main body 58 is thereby exposed. At a time of detecting the height position of the lower end of the grindstone portion 38 of the cutting blade 8 by the blade edge position detecting unit 56, light is emitted from the light emitting window 62b by actuating the light source 62a, the light is applied to the light receiving window 64b of the light receiving unit 64, and the photoelectric conversion unit 64a connected to the light receiving window 64b is made to receive the light. The photoelectric conversion unit 64a includes a light receiving element such as a complementary metal oxide semiconductor (CMOS) sensor, or a charge coupled device (CCD) sensor. The photoelectric conversion unit 64a converts the light into an electric signal having a voltage value corresponding to an amount of the received light, and sends the electric signal to the control unit 22.

When the cutting blade 8 is lowered toward the blade advance portion 60, the light emitted from the light emitting window 62b is gradually interrupted by the cutting blade 8, and the received light amount of the light reaching the light receiving window 64b and received by the photoelectric conversion unit 64a is gradually decreased. Therefore, the height position of the lower end of the grindstone portion 38 of the cutting blade 8 can be detected by analyzing the electric signal output from the photoelectric conversion unit 64a by the control unit 22. When it can be confirmed, on the basis of the received light amount of the light received by the photoelectric conversion unit 64a, that the lower end of the grindstone portion 38 has reached a height position suitable for cutting processing, it is confirmed that the cutting unit 10 has reached a predetermined height position at which the cutting unit 10 is to be positioned at a time of cutting processing, that is, the reference height. The control unit 22 controls a raising and lowering unit 10a, which raises and lowers the cutting unit 10, and the blade edge position detecting unit 56, and the control unit 22 detects the reference height position of the cutting unit 10.

When the workpiece is cut by the cutting blade 8, the grindstone portion 38 is worn, and the diameter thereof is decreased. Therefore, when the setup process is performed before and after the cutting of the workpiece, a change in the reference height of the cutting unit 10 which change corresponds to an amount of wear of the grindstone portion 38 can be measured. Conversely, when the setup process is performed by using the blade edge position detecting unit 56 before and after the cutting of the workpiece, the amount of wear of the grindstone portion 38 can be measured. The cutting apparatus 2 cuts various types of workpieces under processing conditions suitable for the respective types. In addition, there are also various types of cutting blades 8 in order to be able to deal with various kinds of workpieces. In the cutting apparatus 2, an appropriate type of cutting blade matching the type of the workpiece is selected and fitted in advance, and processing is performed under appropriate processing conditions.

Then, when the type of the workpiece is to be changed, or when a problem occurs in the cutting apparatus 2, the old cutting blade is removed from the cutting apparatus 2, and a new cutting blade 8 is fitted to the cutting apparatus 2. The old cutting blade 8 removed from the cutting apparatus 2 is housed and stored in the blade case 42. At this time, a usage history is preferably managed in preparation for the reuse or verification of the cutting blade 8. For example, a total amount of wear of the grindstone portion 38 at the time point is written to the IC tag 52a or 52b. The total wear amount stored in the IC tag 52a or 52b is read when the cutting apparatus 2 uses the old cutting blade 8 temporarily stored in the blade case 42 again. Then, when the reuse of the cutting blade 8 is ended, and the cutting blade 8 is stored in the blade case 42 again, the IC tag 52a or 52b is overwritten with a new total wear amount calculated by adding an amount of wear of the grindstone portion 38 in this reuse to the total wear amount stored in the IC tag 52a or 52b.

When device chips of a new type are to be manufactured by cutting a new type of workpiece by the cutting apparatus 2, it is necessary to search for an optimum type of cutting blade 8 and optimum processing conditions that make it possible to divide the workpiece with high quality. Therefore, in the cutting apparatus 2, test processing is performed while the type of the cutting blade 8 and the processing conditions are changed variously, and a processing result is evaluated. Recently, applications of device chips have been diversified, and a wide variety of device chips supporting the respective applications are manufactured one after another. Therefore, test processing for searching for optimum processing conditions or the like is repeated daily. However, there is a case where a sufficient number of dummy products that can be used as a workpiece at a time of the test processing are not secured, or there is a case where a sufficient time cannot be taken for the test processing. In this case, the mass production of device chips is started while the type of the cutting blade 8 and the processing conditions cannot be verified sufficiently.

There may be a risk of causing a large-scale quality defect problem when device chips are manufactured by cutting workpieces with the cutting blade 8 and the processing conditions selected without undergoing sufficient verification, and then the device chips are put on the market. Furthermore, recently, there has been a remarkable tendency for higher functionality of devices, and quality desired of device chips has tended to become high, so that a degree of difficulty in optimizing the processing conditions has been rising increasingly. Accordingly, processing information may be accumulated while the cutting of the workpiece is performed, and the propriety of the cutting blade and the processing conditions may be determined on the basis of the processing information. In this case, the processing conditions and the like can be optimized by actually processing the workpiece and evaluating a result of the processing. It is therefore possible to pursue processing conditions and the like that make it possible to process the workpiece with high quality even in a case where dummy products imitating the workpiece cannot be prepared sufficiently. In the following, a determining method and a writing method according to the present embodiment will be described in detail.

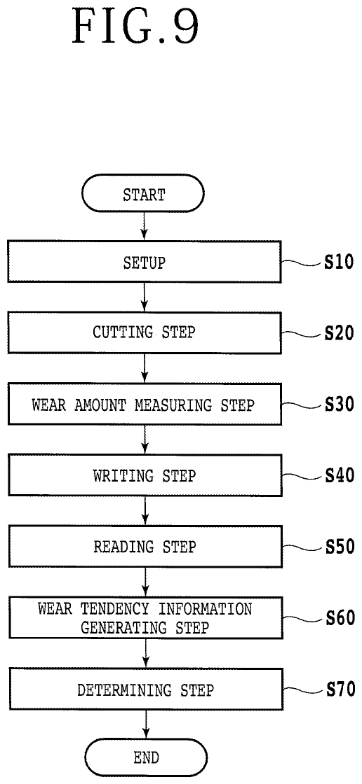

FIG. 9 is a flowchart depicting a flow of steps of a determining method according to the present embodiment. First, the cutting blade 8 is extracted from the blade case 42, and the cutting blade 8 is fitted to the distal end of the spindle 26 by the flange mechanism 28 of the cutting unit 10. The blade case 42 that has become empty is preferably housed and stored in the blade case holder 20. When the blade case 42 provided with the IC tag 52b is housed in the blade case holder 20, the IC tag 52b is disposed in the vicinity of the reader-writer 54, thus making it possible to write information to the IC tag 52b and read information from the IC tag 52b. Alternatively, when the IC tag 52a is provided to the cutting blade 8, the reader-writer (not depicted) is provided to the vicinity of the cutting blade 8 incorporated in the cutting unit 10. It therefore becomes possible to write information to the IC tag 52a and read information from the IC tag 52a.

Thereafter, the blade edge position detecting unit 56 (see FIG. 6A) is used to measure the reference height of the cutting unit 10 when the lower end of the grindstone portion 38 of the cutting blade 8 reaches a predetermined height position. As will be described later, when the reference height of the cutting unit 10 is measured by using the blade edge position detecting unit 56 after the cutting of the workpiece is completed, an amount of change between the reference heights before and after the cutting can be calculated as an amount of wear of the grindstone portion 38. After the setup (S10) is performed, the workpiece is held by the chuck table 12, and cutting is performed according to the processing conditions by using the cutting blade 8 (S20). The processing conditions referred to when the workpiece is cut are registered in the storage unit 22a of the control unit 22 in advance. Here, the processing conditions include various kinds of items such as a rotational speed of the cutting blade 8, a relative feed speed of the cutting unit 10 and the chuck table 12, and the amount of supply of a cutting liquid. It is desirable to register optimum processing conditions in the storage unit 22a in advance according to the type of the workpiece and a desired processing result. The determining method according to the present embodiment can determine the propriety of the processing conditions while performing the cutting of the workpiece. Thus, the contents of the processing conditions can be changed as appropriate depending on a result of the determination. Alternatively, processing conditions desired to be verified are registered in the storage unit 22a.

When the workpiece held by the chuck table 12 is to be cut, the chuck table 12 is rotated such that the processing feed direction of the chuck table 12 and the like coincides with the direction of a planned dividing line of the workpiece. Then, the grindstone portion 38 of the cutting blade 8 is positioned on an extension of the planned dividing line. Then, the cutting blade 8 is rotated at a predetermined rotational speed according to the processing conditions, the cutting unit 10 is positioned at a predetermined height position, and the chuck table 12 and the like are processing-fed to make the grindstone portion 38 of the cutting blade 8 cut into the workpiece. After the cutting of the workpiece is performed along all of the planned dividing lines of the workpiece, the already processed workpiece is removed from the chuck table 12, a new workpiece is held by the chuck table 12, and cutting processing is similarly performed. When the workpiece cutting is repeated, the grindstone portion 38 of the cutting blade 8 is gradually worn, and abrasive grains fall off. However, when the binder is worn, abrasive grains buried in the binder are exposed one after another, and collide with the workpiece, so that the cutting ability of the cutting blade 8 is maintained.

However, when the processing conditions or the type of the cutting blade 8 is not suitable for intended processing, a wear speed of the grindstone portion 38 is slowed, the exposure of new abrasive grains is slowed, and the cutting ability of the cutting blade 8 is decreased, so that high-quality processing may not be able to be performed. This state is referred to also as dulling of the cutting blade 8. Alternatively, when the processing conditions or the type of the cutting blade 8 is not suitable for the intended processing, the wear speed of the grindstone portion 38 is too fast, a large amount of swarf occurs, and abrasive grains are clogged with the swarf. Thus, again, the cutting ability of the cutting blade 8 is decreased, so that high-quality processing may not be able to be performed. This state is referred to also as clogging of the cutting blade 8. Conversely, when a state of wear of the grindstone portion 38 of the cutting blade 8 after the cutting is performed is checked, the propriety of the processing conditions or the type of the cutting blade 8 can be determined. Accordingly, after the cutting of one or a plurality of workpieces is completed, the amount of wear of the grindstone portion 38 is measured by using the blade edge position detecting unit 56 (S30).

More specifically, the height position of the cutting unit 10 when the lower end of the grindstone portion 38 of the cutting blade 8 after the cutting is located at a predetermined height is detected as a reference height position, and an amount of change between the reference height positions of the cutting unit 10 before and after the cutting is calculated as an amount of wear of the grindstone portion 38. Thereafter, the cutting of the workpiece by using the cutting blade 8 may be resumed. When the reference height position of the cutting unit 10 is detected again, the cutting blade 8 can be positioned at a height position suitable for cutting so as to correspond to a state of wear of the grindstone portion 38. Then, when the amount of wear of the cutting blade 8 exceeds a specified value, and thus the cutting blade 8 has reached an end of life, the cutting blade 8 is removed from the cutting unit 10, and is replaced with a new cutting blade 8. Alternatively, the cutting blade 8 may be replaced also when the workpiece is changed or when the contents of the cutting processing are changed.

Next, a writing step S40 is performed which writes processing information to the IC tag 52a or 52b disposed on the cutting blade 8 or the blade case 42. Incidentally, the processing information is information indicating the contents of the cutting of the workpiece which cutting is performed by using the cutting blade 8. More specifically, the processing information includes information about the workpiece cut by the cutting blade 8, the processing conditions under which the workpiece is cut by the cutting blade 8, and the amount of wear of the cutting blade 8 at a time of processing the workpiece. The processing information is, for example, generated each time the reference height position of the cutting unit 10 is detected by using the blade edge position detecting unit 56. The processing information is, for example, written and stored in the IC tag 52a or 52b each time the processing information is generated. Alternatively, the processing information is stored in the storage unit 22a of the control unit 22 each time the processing information is generated, and a plurality of pieces of processing information stored in the storage unit 22a are collectively written to the IC tag 52a or 52b when the cutting blade 8 is replaced.

Here, when merely the life (blade edge remaining amount) of the cutting blade 8 during usage is to be managed, it suffices to write the amount of wear of the grindstone portion 38 as usage history information to the IC tag 52a or 52b. In particular, the total amount of wear of the grindstone portion 38 is necessary to calculate the blade edge remaining amount, and information about changes in the blade edge remaining amount during the use of the cutting blade 8 is not necessary. Therefore, when the amount of wear of the grindstone portion 38 is stored in the IC tag 52a or 52b, it suffices to overwrite the stored information by adding a new amount of wear of the grindstone portion 38 to the stored information and store the resulting information. In addition, in a case where processing conditions under which the workpiece can be processed stably are established, and the cause of a defect occurring in the workpiece or the cutting apparatus 2 when the workpiece is processed under the processing conditions is desired to be analyzed, the established processing conditions do not need to be recorded. It suffices to record usage history information other than the processing conditions, such, for example, as the amount of wear of the grindstone portion 38 of the cutting blade 8, dates and times that the cutting blade 8 is used, the cutting apparatus 2 fitted with the cutting blade 8, the name of an operator who attached the cutting blade 8 to the cutting apparatus 2, and the like.

On the other hand, the determining method according to the present embodiment records and stores, in the IC tag 52a or 52b, processing information including the processing conditions in the cutting performed by using the cutting blade 8 in addition to the amount of wear of the cutting blade 8 and the usage history information. Therefore, when the processing information recorded in the IC tag 52a or 52b is read and analyzed, the propriety of the processing conditions or the like can be determined afterward.

After the cutting blade 8 is detached from the cutting unit 10, the blade case 42 housed in the blade case holder 20 is extracted, and the cutting blade 8 is housed into the blade case 42. Thereafter, an information processing terminal such as a personal computer (PC) connected with the reader-writer capable of transmitting and receiving information by communicating with the IC tag 52a or 52b is prepared in order to verify the processing conditions of the cutting performed by the cutting blade 8. Next, a reading step S50 is performed which reads the processing information written to the IC tag 52a or 52b by using the information processing terminal. In the reading step S50, a preparation for analyzing a wear tendency of the cutting blade 8 is made by reading the processing information written to the IC tag 52a or 52b in the writing step S40.

A wear tendency information generating step S60 is next performed on the information processing terminal. In the wear tendency information generating step S60, wear tendency information is generated by determining the wear tendency of the cutting blade 8 from a relation between a cumulative processing distance (cumulative processing amount) in the workpiece which cumulative processing distance is obtained from the processing information and a cumulative wear amount of the cutting blade 8 which cumulative wear amount corresponds to the cumulative processing distance (cumulative processing amount). Thereafter, a determining step S70 is performed which determines the propriety of the cutting blade 8 or the processing conditions for the workpiece by further using the information processing terminal on the basis of the wear tendency information generated in the wear tendency information generating step S60.

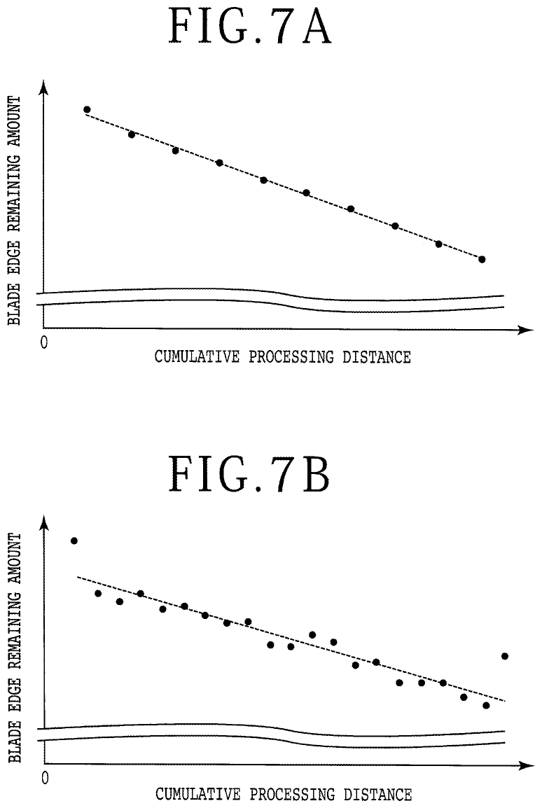

In the following, description will be made of an example of a procedure for determining the propriety of the processing conditions or the cutting blade 8 on the basis of the processing information read from the IC tag 52a or 52b in the reading step S50. For example, the wear tendency information generating step S60 generates a graph indicating the wear tendency of the cutting blade 8 on the basis of the processing information read from the IC tag 52a or 52b. FIG. 7A and FIG. 7B are an example of graphs indicating wear tendencies of the cutting blade 8. The axes of abscissas of the graphs depicted in FIGS. 7A and 7B indicate the cumulative processing distance (cumulative processing amount) in the workpiece. The axes of ordinates of the graphs indicate the blade edge remaining amount of the grindstone portion 38 of the cutting blade 8. The blade edge remaining amount can be calculated by subtracting the cumulative wear amount of the cutting blade 8 which cumulative wear amount corresponds to the cumulative processing distance in the workpiece from an initial blade edge remaining amount of the grindstone portion 38 of the cutting blade 8. That is, the graphs can also be said to be graphs indicating a relation between the cumulative processing distance (cumulative processing amount) and the cumulative wear amount.

Each dot in the graphs depicted in FIG. 7A and FIG. 7B indicates the cumulative wear amount of the grindstone portion 38 at a point in time that the amount of wear of the grindstone portion 38 of the cutting blade 8 is measured while the cutting blade 8 proceeds with the cutting of the workpiece and the cumulative processing distance for which the cutting blade 8 performs processing until a time of measurement. Broken lines in the graphs depicted in FIG. 7A and FIG. 7B represent straight lines approximating each dot. Incidentally, the two graphs each indicate the wear tendency of the cutting blade 8 in a case where a workpiece of a same type is cut without the processing conditions being changed. In addition, because the scales of the axes of ordinates and the axes of abscissas of the two graphs are not identical, there is no meaning in simply comparing apparent slopes of the two approximate straight lines with each other. When the two graphs are then compared with each other, it is understood that each dot on the graph depicted in FIG. 7A does not deviate greatly from the approximate straight line, and that there are thus relatively small variations in the wear tendency of the grindstone portion 38. On the other hand, it is understood that each dot on the graph depicted in FIG. 7B deviates from the approximate straight line greatly, and that there are thus relatively large variations in the wear tendency of the grindstone portion 38.

Here, the graph depicted in FIG. 7B has a region in which the blade edge remaining amount appears to be increased when the cumulative processing distance of the cutting blade 8 is increased. An effect of a detection error of the blade edge position detecting unit 56 is considered to be a cause of this. Alternatively, considered as a cause of this is insufficient preparatory processing operation (idling) at a time of a start of processing and thermal expansion or contraction of the cutting blade 8 due to a change in the temperature of the cutting blade 8 during the processing. In a case where the wear tendency of the grindstone portion 38 of the cutting blade 8 is one as depicted in FIG. 7A, it is considered that the workpiece can be cut in a stable manner and with high quality. In this case, it can be determined that the cutting blade 8 and the processing conditions are suitable for the workpiece. On the other hand, in a case where the wear tendency of the grindstone portion 38 of the cutting blade 8 is one as depicted in FIG. 7B, it is considered that the workpiece cannot be cut in a stable manner and with high quality. In this case, it can be determined that the cutting blade 8 or the processing conditions are not suitable for the workpiece.

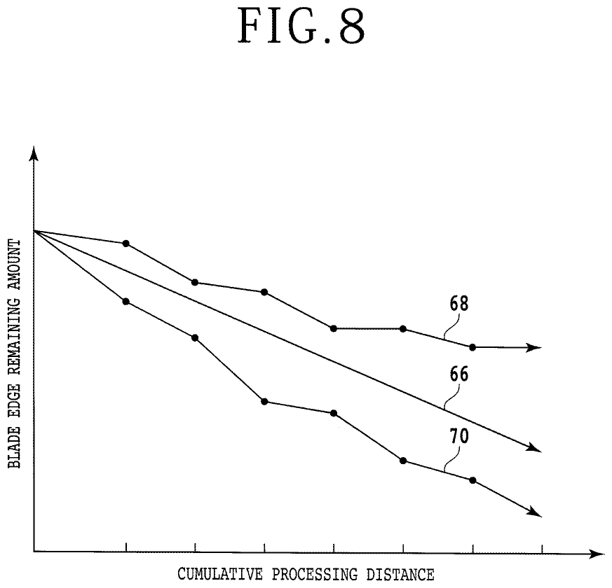

In addition, the propriety of the cutting blade 8 or the processing conditions can be determined on the basis of not only variations in the wear tendency of the grindstone portion 38 of the cutting blade 8 but also slopes. FIG. 8 is a graph schematically depicting a straight line graph 66 indicating an ideal wear tendency of the grindstone portion 38 of the cutting blade 8 and polygonal line graphs 68 and 70 indicating wear tendencies of the grindstone portion 38 of the cutting blade 8 which wear tendencies are obtained when the cutting of the workpiece is repeated. The straight line graph 66 indicating the ideal wear tendency indicates the wear tendency of the grindstone portion 38 when the grindstone portion 38 is worn moderately and the cutting ability of the cutting blade 8 is maintained at a high level. When the polygonal line graphs 68 and 70 indicating the wear tendencies of the grindstone portion 38 which wear tendencies are obtained when the cutting of the workpiece is repeated do not greatly deviate from the straight line graph 66, it can be determined that the type of the cutting blade 8 and the processing conditions are suitable for the cutting of the workpiece. On the other hand, when the polygonal line graphs 68 and 70 greatly deviate from the straight line graph 66, it is considered that dulling or clogging has occurred, and that the cutting ability of the cutting blade 8 is thereby decreased. That is, it can be determined that the type of the cutting blade 8 or the processing conditions are not suitable for the cutting of the workpiece.

Further, an allowable amount of deviation of the polygonal line graphs 68 and 70 from the straight line graph 66 may be determined in advance as a determination condition for determining the propriety of the cutting blade 8 or the processing conditions for the workpiece. This allowable amount does not need to be fixed but may be determined as a ratio of the amount of wear (blade edge remaining amount) of the grindstone portion 38 to the cumulative processing distance of the cutting blade 8 in the workpiece. When this deviation is present in an allowable range, it can be determined that the cutting blade 8 or the like is suitable for the purpose of the processing. When the deviation is outside the allowable range, it can be determined that the cutting blade 8 or the like is not suitable. Incidentally, the straight line graph 66 indicating the ideal wear tendency of the cutting blade 8 is a form of a kind of reference wear tendency information about the reference wear tendency of the cutting blade 8. In addition, the polygonal line graphs 68 and 70 indicating wear tendencies of the cutting blade 8 are a form of a kind of the wear tendency information.

The above description is description of generation of the polygonal line graphs 68 and 70 as graphs functioning as the wear tendency information as an example of the wear tendency information generating step S60. In addition, the above description is description of determination of the propriety of the cutting blade 8 or the like by comparing the straight line graph 66 as a reference graph functioning as the reference wear tendency information and the polygonal line graphs 68 and 70 with each other as an example of the determining step S70. However, the forms of the reference wear tendency information and the wear tendency information are not limited to this, and the method of determining the propriety of the cutting blade 8 or the like by comparing the reference wear tendency information and the wear tendency information with each other is not limited to this either.

In addition, a storage unit of the information processing terminal may store a program that determines the propriety of the cutting blade 8 or the processing conditions for the workpiece from the wear tendency information. In addition, the allowable amount of deviation from the straight line graph 66 may be registered as a determination condition in advance in the storage unit of the information processing terminal that generates the wear tendency information. Then, the propriety of the cutting blade 8 or the like may be determined automatically on the basis of the allowable amount of deviation from the straight line graph 66 which allowable amount is registered in the storage unit by executing the program on the information processing terminal.

The information processing terminal that performs the reading step S50, the wear tendency information generating step S60, and the determining step S70 is, for example, installed within a device chip factory in which the cutting apparatus 2 is installed. In this case, an operator belonging to the device chip factory performs each step by using the information processing terminal.

Alternatively, the information processing terminal may be possessed by a manufacturer of the cutting apparatus 2 or the cutting blade 8. For example, the cutting blade 8 that has reached an end of life may be collected and disposed of by the manufacturer of the cutting apparatus 2 or the cutting blade 8. At this time, the manufacturer may read the processing information written to the IC tag 52a or 52b on the information processing terminal and determine the propriety of the cutting blade 8 or the processing conditions for the workpiece. In this case, the manufacturer that knows the characteristics of the cutting blade 8 or the structure of the cutting apparatus 2 well can determine the propriety of the processing conditions on the basis of deep knowledge. It is therefore possible for the manufacturer also to feed back processing conditions suitable for obtaining a desired processing result to a user of the cutting apparatus 2 or the like on the basis of a determination result.

Thus, each step of the determining method according to the present embodiment may be consistently performed by the user of the cutting apparatus 2. Alternatively, steps to the writing step S40 may be performed by the user of the cutting apparatus 2 or the like, and steps from the reading step S50 on down may be performed by the manufacturer of the cutting apparatus 2 or the like. The writing method of writing the processing information to the IC tag 52a or 52b so as to subsequently enable the determination of the propriety of the processing conditions on the basis of the processing information can be said to be one aspect of the present invention. In addition, the determining method that reads the processing information written to the IC tag 52a or 52b and determines the propriety of the processing conditions on the basis of the processing information can also be said to be one aspect of the present invention.

Incidentally, in a case where it is determined in the determining step S70 that the cutting blade 8 or the processing conditions are not suitable, the type of the cutting blade 8 or the processing conditions are preferably changed. Then, it is preferable to perform the determining method according to the present embodiment again, and thereby further determine the propriety of the changed type of the cutting blade 8 or the changed processing conditions. In addition, even in a case where it is determined in the determining step S70 that the cutting blade 8 or the processing conditions are suitable, the cutting blade 8 or the processing conditions may be changed so that a more desirable processing result can be obtained. As described above, according to the determining method and the writing method in accordance with the present embodiment, it is possible to determine whether or not the cutting blade 8 or the processing conditions are suitable for the cutting of the workpiece on the basis of the processing information obtained by processing the workpiece. That is, even in a case where the test processing for searching for optimum processing conditions cannot be performed sufficiently, the propriety of the cutting blade 8 or the processing conditions can be determined in a process of proceeding with the cutting of the workpiece.

It is to be noted that while description has been made of a case where the wear tendency information is generated in the form of a graph in the foregoing embodiment, the determining method according to one aspect of the present invention is not limited to this. That is, in the wear tendency information generating step S60, the wear tendency information may be generated in a form other than a graph. In a case where the information processing terminal determines the propriety of the cutting blade 8 or the like according to a program, for example, the wear tendency information does not need to be expressed in the form of a graph as visual information but may be constituted by a data set of the cumulative processing distance (cumulative processing amount) and the cumulative wear amount of the cutting blade 8, for example.

Further, in the foregoing embodiment, description has been made of a case where a graph indicating wear tendency information is generated when processing is performed under fixed processing conditions. However, one aspect of the present invention is not limited to this. That is, a graph indicating wear tendency information may be generated in a case of proceeding with the cutting of the workpiece under various different processing conditions during a period from the fitting of one cutting blade 8 to the cutting unit 10 of the cutting apparatus 2 to the removal of the cutting blade 8. In this case, the graph indicating the wear tendency information continuously depicts a plurality of wear tendencies of the cutting blade 8 when the workpiece is cut under the respective processing conditions. Each wear tendency indicated by this graph may be evaluated individually, and the relative superiority of each processing condition may be determined by comparing each wear tendency. It is possible to proceed with a search for processing conditions suitable for the workpiece efficiently when the relative superiority of various processing conditions can be thus determined by cutting the workpiece with one cutting blade 8.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A determining method for determining propriety of a grindstone tool or a processing condition, the determining method comprising:
a writing step of performing processing according to the processing condition by using the grindstone tool, and writing a plurality of pieces of processing information of the grindstone tool to an integrated circuit tag provided to the grindstone tool or a case configured to house the grindstone tool, the plurality of pieces of processing information of the grindstone tool each including information about a workpiece processed by the grindstone tool, the processing condition under which the workpiece is processed by the grindstone tool, and an amount of wear of the grindstone tool at a time of processing the workpiece;
a wear tendency information generating step of reading the processing information written to the integrated circuit tag in the writing step, and generating wear tendency information by determining a wear tendency of the grindstone tool from a relation between a cumulative processing amount of the workpiece, the cumulative processing amount being obtained from the processing information, and a cumulative wear amount of the grindstone tool, the cumulative wear amount corresponding to the cumulative processing amount; and
a determining step of making determination of the propriety of the grindstone tool or the processing condition for the workpiece on a basis of the wear tendency information generated in the wear tendency information generating step.

2. A writing method of writing processing information of a grindstone tool to an integrated circuit tag, the writing method comprising:
performing processing according to a processing condition by using the grindstone tool; and
writing the processing information of the grindstone tool to the integrated circuit tag provided to the grindstone tool or a case configured to house the grindstone tool, the processing information of the grindstone tool including information about a workpiece processed by the grindstone tool, the processing condition under which the workpiece is processed by the grindstone tool, and an amount of wear of the grindstone tool at a time of processing the workpiece.

3. A determining method of determining propriety of a grindstone tool or a processing condition, the determining method comprising:
a wear tendency information generating step of reading processing information written to an integrated circuit tag to which the processing information is written and which is provided to the grindstone tool or a case configured to house the grindstone tool, the processing information including information about a workpiece cut by the grindstone tool, the processing condition under which the workpiece is processed by the grindstone tool, and an amount of wear of the grindstone tool at a time of processing the workpiece, and generating wear tendency information by determining a wear tendency of the grindstone tool from a relation between a cumulative processing amount of the workpiece, the cumulative processing amount being obtained from the processing information, and a cumulative wear amount of the grindstone tool, the cumulative wear amount corresponding to the cumulative processing amount; and
a determining step of making determination of the propriety of the grindstone tool or the processing condition for the workpiece on a basis of the wear tendency information generated in the wear tendency information generating step.

4. The determining method according to claim 1, wherein
the wear tendency information generating step generates a graph indicating the wear tendency of the grindstone tool.

5. The determining method according to claim 1, wherein
the determining step makes the determination by comparing reference wear tendency information about a reference wear tendency of the grindstone tool and the wear tendency information with each other.

6. The determining method according to claim 5, wherein
the wear tendency information generating step generates a graph functioning as the wear tendency information, and
the determining step makes the determination by comparing a reference graph functioning as the reference wear tendency information and the graph with each other.

7. The determining method according to claim 1, wherein
the grindstone tool is a cutting blade.
